(19) United States
(12) Patent Application Publication
(10) Pub. No.: US 2026/0291444 A1
(43) Pub. Date: Sep. 24, 2026

(54) AMPLIFIER SYSTEM WITH OUTPUT STAGE

(71) Applicant: HARMAN INTERNATIONAL INDUSTRIES, INCORPORATED, Stamford, CT (US)

(72) Inventors: Dimitri DANYUK, Stamford, CT (US); Danial SHIMIAEI, Sherman Oaks, CA (US)

(73) Assignee: HARMAN INTERNATIONAL INDUSTRIES, INCORPORATED, Stamford, CT (US)

(21) Appl. No.: 19/490,869

(22) PCT Filed: Jun. 30, 2023
(86) PCT No.: PCT/US2023/026744

§ 371 Date: Dec. 5, 2025

(51) Int. Cl. H03F 1/32; H03F 3/183

(52) U.S. Cl. CPC H03F 1/32; H03F 3/183; H03F 2200/03

(57) ABSTRACT

In at least one embodiment, an amplifier is provided. The amplifier includes an input stage, a plurality of output stages, and a combining stage. The input stage includes a first input transistor and a second input transistor to receive an input signal. Each output stage includes at least one output resistor. The plurality of output stages is configured to operate in a one of a push mode to output a positive cycle of the input signal to a load and a pull mode to absorb a negative cycle of the input signal from the load. The combining stage includes a plurality of combining resistors, each combining resistor forming a star connection with the output resistors for each output stage to receive a first voltage therefrom and to generate an output voltage based on the first voltage to produce a low distortion output signal at the load.

### TECHNICAL FIELD

Aspects disclosed herein generally relate to an amplifier system having output stage. These aspects and others will be discussed in more detail below.

### BACKGROUND

Class AB amplifiers generally combine Class A and Class B amplifiers to provide an amplifier having more efficiency than the Class A amplifier but with lower distortion than a Class B amplifier. This may be achieved by biasing transistors so that such transistors conduct when the output signal is close to zero (e.g., the point where Class B amplifiers introduce non-linearities).

For smaller signals, both transistors of the Class AB amplifier are active thereby behaving as a Class A amplifier. For larger signal excursions, one transistor may be active for each half of a waveform thereby acting like a Class B amplifier.

### SUMMARY

In at least one embodiment, an amplifier is provided. The amplifier includes an input stage, a plurality of output stages, and a combining stage. The input stage includes a first input transistor and a second input transistor to receive an input signal. Each output stage includes at least one output resistor. The plurality of output stages is configured to operate in a one of a push mode to output a positive cycle of the input signal to a load and a pull mode to absorb a negative cycle of the input signal from the load. The combining stage includes a plurality of combining resistors, each combining resistor forming a star connection with the output resistors for each output stage to receive a first voltage therefrom and to generate an output voltage based on the first voltage to produce a low distortion output signal at the load.

In at least another embodiment, an amplifier is provided. The amplifier includes an input stage, a plurality of output stages, and a combining stage. The input stage includes a first input transistor and a second input transistor to receive an input signal. Each output stage includes at least one current setting resistor, the plurality of output stages being configured to operate in a one of a push mode to output a positive cycle of the input signal to a load and a pull mode to absorb a negative cycle of the input signal from the load. The combining stage includes a plurality of combining resistors, each combining resistor being positioned in series each output stage, respectively, and forming a delta connection with a corresponding current setting resistor to receive a first voltage therefrom and to generate an output voltage based on the first voltage to produce a low distortion output signal at the load.

In at least another embodiment, an amplifier is provided. The amplifier includes a plurality of output stages and a combining stage. Each output stage includes at least one output resistor, the plurality of output stages being configured to operate in a one of a push mode to output a positive cycle of an input signal to a load and a pull mode to absorb a negative cycle of the input signal from the load. The combining stage includes a plurality of combining resistors, each combining resistor forming a star connection with the at least one output resistor for each output stage to receive a first voltage therefrom and to generate an output voltage based on the first voltage to produce a low distortion output signal at the load.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 depicts one example of an amplifier;

FIG. 2 depicts one example of plot showing an incremental gain associated with a different bias setting for the amplifier of FIG. 1;

FIG. 3 depicts one example of a plot showing an individual harmonic distortion as a function of an output voltage for an overbiased push-pull output stage of the amplifier of FIG. 1;

FIG. 4 depicts an amplifier in accordance with one embodiment of the present disclosure;

FIGS. 5A and 5B depict a simulation of an incremental gain with different bias setting for individual push-pull complementary pairs and an output stage as a whole in accordance with one embodiment;

FIG. 6 depicts one example of a plot showing an individual harmonic distortion as a function of an output voltage for an overbiased push-pull output stage of the amplifier of FIG. 4:

FIG. 7 depicts an amplifier in accordance with one embodiment of the present disclosure; and

FIG. 8 depict simplified gain plots that illustrate characteristics for the disclosed amplifiers of FIGS. 4 and 7 in accordance with one embodiment of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

In general, the present disclosure provides, but not limited to, a single-ended push-pull amplifier that includes a plurality of complementary single-ended push-pull circuits connected, for example, in parallel across a load. Each push pull circuit has complementary transistor pairs and an output connected together through a resistor network to drive a common load. Inputs of the push pull circuits are connected with a driver circuit connected to receive an input signal. Each push pull transistor pair has emitter resistors. The value of the emitter resistors may be different for each pair. Each push pull transistor pair may be operated in Class A with different quiescent current at small signal levels, and each push pull transistor pair may be operated in Class B at large signal levels. A resistor network may combine the output signals from each push pull transistor pair thereby producing a low distortion output signal at the load terminals. The circuit is less sensitive to the bias (quiescent current) setting than existing solutions. Aspects of the present disclosure may provide, but not limited to, a decrease in high-order harmonics in a transition region from claim A to claim B. In addition, the present disclosure may provide an amplifier that possess reduced sensitivity to bias setting. The amplifier of the present disclosure provides, among other things, a simple solution that generally requires less (e.g., few) extra passive components.’

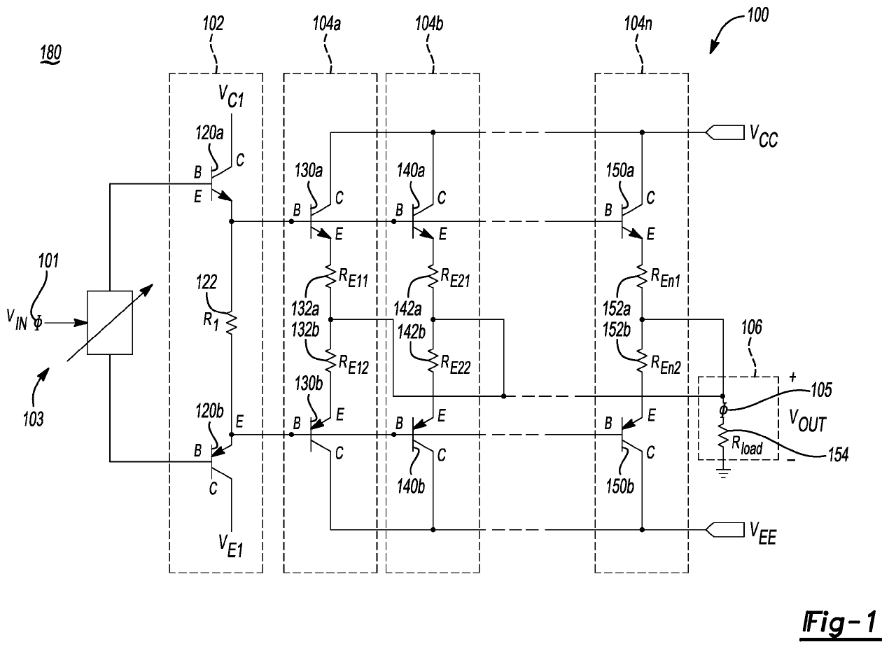

FIG. 1 depicts one example of an amplifier 100 (e.g., an audio amplifier). In one example, the amplifier 100 may be implemented as a Class AB amplifier. In general, the amplifier 100 may produce high current, voltage or power for a given audio input signal. The amplifier 100 may produce reduced cross-over distortion under the optimum bias condition. Various advantages attributed to the amplifier 100, when implemented as an AB amplifier, may include high efficiency and higher output power in comparison to Class A amplifiers.

The amplifier 100 includes an input stage 102, a plurality of output stages 104a-104n and a combining stage 106. It is recognized that the number of output stages 104a-104n may vary based on the desired criteria of a particular implementation. The amplifier 100 includes a biasing network 103 for forming a first terminal (or input terminal) 101 to receive an input voltage, V_{IN}. It is recognized that the amplifiers as set forth herein may be used to amplify any input signal for any number of applications. Various examples may include the disclosed amplifiers may amplify an incoming audio signal, etc. The amplifier 100 also has an output terminal 105 for outputting an output voltage, V_{OUT}. The amplifier 100 is generally configured to operate in a push mode and in a pull mode. In the push mode, the amplifier 100 generates positive half cycle (push) V_{OUT} associated with the input voltage V_{IN}. In the pull mode, the amplifier 100 produces on a negative half cycle (pull) V_{OUT} associated with the input.

The input stage 102 may include a plurality of input switches (or input transistors) 120a, 120b and aa current setting resistor 122 (or R1). The biasing network 103 sets a current for the input transistors 120a, 120b and for the output stages 104a. In general, the biasing network 103 sets the current for the input transistors 120a, 120b and first output devices (or first output transistors) 130a-130b within an input signal. In general, the input may be zero and the output is also zero. If no current is being transmitted through the biasing network 103, then the amplifier 100 will be a class B amplifier. If a small amount of current is passing through the biasing network 103, (e.g., a small amount of current compared to an output current swing) in the absence of an input signal) the amplifier 100 will be a class B amplifier.

The first output stage 104a includes first output devices (e.g., first output switches or first output transistors) 130a, 130b and current setting resistors 132a (or R_{E11}), 132b (or R_{E12}). The second output stage 104b includes second output devices (or a pair) 140a, 140b (e.g., second output switches or second output transistors) and current setting resistors 142a (or R_{E21}), 142b (or R_{E22}). The third output stage 104c includes third output devices 150a, 150b (e.g., third output switches or third output switches transistors) and current setting resistors 152a, (or R_{En1}), 152b (or R_{En2}). The common points for each current setting resistor pair are connected together in the combining stage 106 (or combining stage 106). The combining stage 106 blends/mixes output currents from each of the individual output stages 104a-104n and includes a resistor 154 (or R_{load}).

The amplifier 100 generally operates in the following manner in connection with the push mode. As shown at the input stage 102, a first voltage (e.g., V_{C1}) is provided to a collector of the input transistor 120a. The input voltage (e.g., V_{IN}) is provided to a base of the input transistor 120a. Thus, when the first voltage V_{C1} is applied to the input transistor 120a, the input transistor 120a generates a voltage that is provided to a base terminals of the output transistors 130a, 140a, and 150a of the output stages 104a, 104b, and 104c.

A third voltage (e.g., V_{CC}) is provided to collectors of the output transistors 130a, 140a, and 150b of the output stages 104a, 104b, and 104n, respectively such that the output transistors 130a, 140a, and 150a provide a first output voltage (or a first output current). It is recognized that the input transistor 120a provides a voltage to the bases of the output transistors 130a, 140a, and 150a when the third voltage V_{CC} is applied to the output transistors 130a, 140a, and 150a. In general, the current setting resistors 132a, 142a, and 152a determine the first output current from the output stages 104a, 104b, and 104n, respectively, based on their corresponding resistance values. Each of the output stages 104a, 104b, and 104b generate the output voltage V_{OUT} (e.g., a positive half cycle of the output voltage) that is provided to the combining stage 106 (or resistor 154 (e.g., R_{load})). At least one controller 180 (“the controller 180”) may be operably coupled to the amplifier 100 to selectively apply the first voltage V_{C1}, the second voltage V_{E1}, the third voltage V_{CC}, and the fourth voltage V_{EE}. In short, in the push mode, the direction of the current is positive via the V_{CC} rail, through the output transistors 130a, 140a, 150a, the current setting resistors 132a, 142b, and 152b, respectively, to the resistor 154 of the combining stage 106 and then to ground.

As noted above, in an effort to provide a negative half cycle of the output voltage V_{OUT}, the amplifier 100 also operates in the pull mode. Through the negative half cycle of the output voltage V_{OUT}, the output current is returned back through the current setting resistors 132b, 142b, 152b of the output stages 104a, 104b, 104n, respectively, which each provide a current that passes through the output transistors 130b, 140b, 150b of the corresponding output stages 104a-104n, respectively. In this case, the controller 180 may apply the fourth voltage (e.g., V_{EE}) to the output transistors 130b, 140b, and 150b to enable the current flow from the emitters to the collectors for these output transistors 130b, 140b, and 150b. In the pull mode, the output devices 130b, 140b, and 150b are switched on when no voltage is presented to the bases of these output transistors 130b, 140b, and 150b. In short, in the pull mode, the direction of current flows through the current setting resistors 132b, 142b, 152b, and through the output transistors 130b, 140b, and 150b, respectively.

In general, by adding the corresponding output stages 104a-104n, the amplifier 100 is generally configured to increase output capability for driving a load (e.g., R_{load}) with a final output voltage (e.g., V_{OUT}). In one example, the amplifier 100 is a class AB complementary arrangement including the input transistors 120a, 120b that form an emitter follower along with the output transistors 130a and 130b, 140a and 140b, and 150a and 150b. The current setting resistor 122 sets an idle current for the input transistors 120a, 120b. The use of multiple output transistors 130a-130b, 140a-140b, and 150a-150b in the class AB configuration results in a high peak output current capability, a distortion reduction, a higher linearity, an extended bandwidth, and stress-free reliability. The resistors 132a-132b, 142a-142b, and 152a-152b provide a thermal bias stability for the various output stages 104a-104n and also provide an output current balance between the individual output pairs of output transistors 130a-130b, 140a-140b, and 150a-150b. The resistance values for the resistors 132a, 132b, 142a, 142b, 152a, and 152b may be similar to one another.

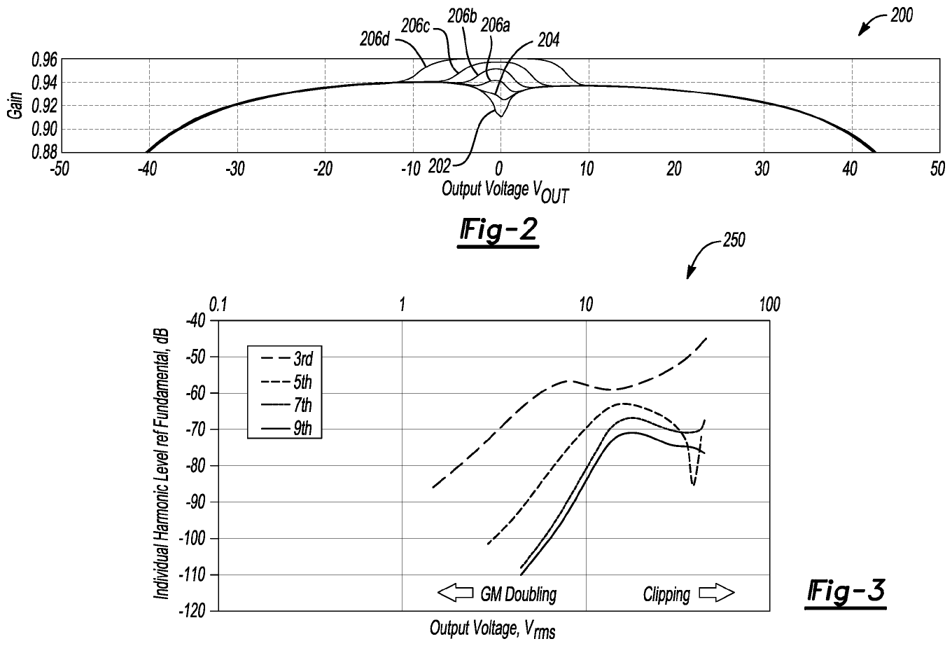

FIG. 2 depicts one example of plots 200 illustrating an incremental gain associated with a different bias setting for the amplifier 100 of FIG. 1. The plot 200 illustrates the gain of the amplifier 100 (see y axis for the gain scale) against an output voltage for various bias/quiescent current in output stages 104a-104n. In general, when the amplifier 100 is producing a low output current, the output is provided by all output transistors 130a-130b, 140a-104b, and 150a-150b and an output impedance may be close to a resistance of the resistor 152a being divided by 2n (e.g., or REN1/2n, providing that R_{E11}=R_{E21}=R_{EN1}=R_{E12}=R_{E22}=R_{EN2}, n is the number of the output stages). The gain of the amplifier 100 is equal to R_{load}/(R_{load}+R_{EN1}/2n). When the amplifier 100 generates a high output current (i.e., when only a single output transistor 130a or 130b, 140a or 140b, 150a or 150b is conducted and provides an output current to the resistor 154 (or R_{load})). In this case the gain of the amplifier 100 is equal to R_{load}/(R_{load}+R_{EN1}/n). An output impedance of the amplifier 100 for high output current is close to an impedance of the resistor 152a (or 152b), being divided by n. The plot 200 illustrates the amplifier gain at low and high output currents and the transition. The transition region is rather sharp, and that sharp change of the gain generates higher order harmonics. FIG. 2 generally illustrates the condition when the output transistors 130a and 130b, 140a and 140b, and/or 150a and 150b are working at different bias level. When the amplifier 100 is under biased (the quiescent current is too low), a dip in the gain is experienced and expected. When the above noted output transistors 130a and 130b, 140a and 140b, and/or 150a and 150b are optimally biased, the gain is the most linear. The region of the optimum bias is narrow, and strongly depends on the device temperature. FIG. 2 generally illustrates gain plots 202, 204, and 206a-206d. Gain plot 202 generally corresponds to the condition in which the amplifier 100 is under biased. Gain plot 204 generally corresponds to the condition in which the amplifier 100 is exhibiting an optimal bias. Gain plot 206a-206d generally corresponds to the condition in which the amplifier 100 operates under elevated levels of bias (overbias). FIG. 3 provides a plot 250 having individual harmonics distortion as a function of an output voltage (e.g., V_{OUT}) as shown in connection with FIG. 1 for one example of an overbiased push-pull output stage.

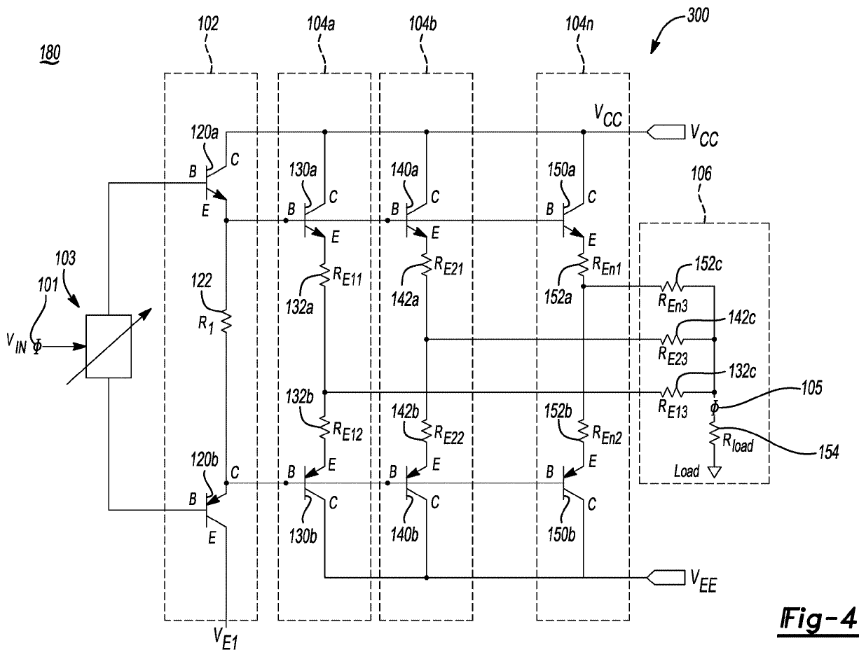

FIG. 4 depicts an amplifier 300 in accordance with one embodiment of the present disclosure. In one example, the amplifier 300 may be implemented as a Class AB amplifier. Similar to the amplifier 100 noted above in connection with FIG. 1, the amplifier 300 may produce high current, voltage or power at the load terminals for a given audio input signal. The amplifier 300 may eliminate cross-over distortion. Various advantages attributed to the amplifier 300 may include high efficiency and amplification in comparison to Class A amplifiers, and a linear frequency response since amplitude and the phase of the output signal may be the same as the input signal. The amplifier 300 may also provide low distortion and desensitize the output stage bias setting.

The amplifier 300 includes the input stage 102, the plurality of output stages 104a-104n and the combining stage 106. It is recognized that the number of the output stages 104a-104n may vary based on the desired criteria of a particular implementation. The amplifier 300 includes the biasing network 103 for receiving an input voltage, V_{IN}. The input voltage, (e.g., an audio signal) that requires amplification V_{IN} is present on the first terminal 101. The amplifier 300 includes an output terminal 105 to provide the output signal V_{OUT}. Similar to the amplifier 100 noted above, the amplifier 300 is generally configured to also operate in the push mode and in the pull mode.

Also similar to the amplifier 100 as noted above, the amplifier 300 includes first output stage 104a having the first output transistors 130a, 130b and the current setting resistors 132a (or R_{E11}), 132b (or R_{E12}). The second output stage 104b includes the output transistors 140a, 140b and current setting resistors 142a (or R_{E21}), 142b (or R_{E22}). The third output stage 104c includes the third output switches 150a, 150b and the current setting resistors 152a, (or R_{En1}), 152b (or R_{En2}). The common points for each current setting resistor pair are connected together in the output network 106 (or combining stage 106). The combining stage 106 includes resistor 132c (R_{E13}), resistor 142c (R_{E23}), and resistor 152c (R_{E33}) (or combining resistors). The resistor 132c (R_{E13}) as positioned in the combining stage 106 is electrically coupled to the first output stage 104a. The resistor 142c (R_{E23}) as positioned in the combining stage 106 is electrically coupled to the output stage 104b. The resistor 152c (R_{En3}) as positioned in the combining stage 106 is electrically coupled to the output stage 104n. The resistors 132c, 142c, and 152c of the combining stage 106 form a star connection with the resistors 132a, 132b, 142a, 142c, and 152a, 152c. Alternatively, the resistors 132c, 142c, and 152c are positioned in series with the resistors 132a, 142a, and 152a, respectively, in the push mode. The resistors 132c, 142c, and 152c are positioned in series with the resistors 132b, 142b, and 152b, respectively, in the pull mode. In general, the combining stage 106 blends/mixes output currents from each of the individual output stages 104a-104n.

The amplifier 100 generally operates in the following manner in connection with the push mode. As shown at the input stage 102, the first voltage (e.g., V_{C1}) is provided to a collector of the input transistor 120a. The input voltage (e.g., V_{IN}) is provided to a base of the input transistor 120a. Thus, when the first voltage V_{C1} is applied to the input transistor 120a, the input transistor 120a generates a voltage that is provided to a base of the output transistors 130a, 140a, and 150a of the output stages 104a, 104b, and 104c.

The third voltage (e.g., V_{CC}) is provided to collectors of the output transistors 130a, 140a, and 150b of the output stages 104a, 104b, and 104n, respectively such that the output transistors 130a, 140a, and 150a provide a first output voltage (or a first output current) through the resistors 132a, 142a, 152a, respectively, to the resistors 132c, 142c, and 152c of the combining stage 106. It is recognized that the input transistor 120a provides a voltage to the bases of the output transistors 130a, 140a, and 150a when the third voltage V_{CC} is applied to the output transistors 130a, 140a, and 150a. In general, the resistors 132a, 142a, and 152a determine a first output current from the output stages 104a, 104b, and 104n, respectively, based on their corresponding resistance values. Each of the output stages 104a, 104b, and 104b provide the first voltage to the resistors 132c, 142c, and 152c, respectively, of the combining stage 106. The combining stage 106 sums the current through the resistors 132c, 142c, 152c and provides the current to the resistor 154 (e.g., R_{load})). The resistors 132c, 142c, and 152c are positioned in series with the resistors 132a, 142a, and 152a, respectively. The resistors 132c, 142c, and 152c may be sufficiently small to achieve a low impedance output and resistors 132a, 142a, and 152a (132b, 142b, and 152b) may be large enough to prevent excessive quiescent current. In short, in the push mode, the direction of the current is positive via the V_{CC} rail, through the output transistors 130a, 140a, 150a, the resistors 132a, 142a, and 152a, respectively, to the resistors 132c, 142c, and 152c, respectively, and to the resistor 154 of the combining stage 106 and then to ground.

In general, the resistor 132a may be equal to the resistor 132b, the resistor 142a may be equal to the resistor 142b, and the resistor 152a may be equal to the resistor 152b (or R_{E11}=R_{E12}; R_{E21}=R_{E22}; . . . . R_{En1}=R_{En2}). In addition, the following equation may apply for the resistors 132a, 132b, and 132c; 142a, 142b, and 142c, and 152a, 152b, and 152c:

$${R}_{E 11} + {R}_{E 13} = {R}_{E 21} + {R}_{E 23} = … {R}_{En 1} + {R}_{E n 3} .$$

By setting the various resistance values in accordance to that noted above and/or in addition to star connection formed between the resistors 132c, 142c, and 152c of the combining stage 106 with the resistors 132a, 132b, 142a, 142c, and 152a, 152c of the output stages 104a-104n, these aspects enable the amplifier 300 to, among other things, provide a driving output from each of the output stages 104a-104n and the combining stage 106 to produce a low distortion output signal at the load (or at the resistor 156). Each of the output stages 104a, 104b, and 104b and the resistors 132c, 142c, 152c of the combining stage 106 generate the output voltage V_{OUT} (e.g., a positive half cycle of the output voltage) that is provided to the resistor 154 (e.g., R_{load})). The controller 180 may be operably coupled to the amplifier 100 to selectively apply the first voltage V_{C1}, the second voltage V_{E1}, the third voltage V_{CC}, and the fourth voltage V_{EE}.

As noted above, in an effort to provide a negative half cycle of the output voltage V_{OUT}, the amplifier 100 also operates in the pull mode through the negative half cycle of the output voltage (V_{OUT}), the output current is returned back through the resistors 132c, 142c, 152c of the combining stage 106 and through the resistors 132b, 142b, 152b of the output stages 104a, 104b, 104n, respectively. The resistors 132b, 132c, 142b, 142c, and 152b, 152c provide a current that passes through the output transistors 130b, 140b, 150b of the corresponding output stages 104a-104n, respectively. In this case, the controller 180 may apply the fourth voltage (e.g., V_{EE}) to the output transistors 130b, 140b, and 150b to enable the current flow from the emitters to the collectors for these output transistors 130b, 140b, and 150b. In the pull mode, the output devices 130b, 140b, and 150b are switched on when no voltage is presented to the bases of these output transistors 130b, 140b, and 150b. In short, in the pull mode, the direction of current flows through the resistors 132b, 132c, 142b, 142c, 152b, 152c and through the output transistors 130b, 140b, and 150b, respectively.

In general, by adding the corresponding output stages 104a-104n, the amplifier 100 is generally configured to increase output capability for driving a load (e.g., R_{load}) with a final output voltage (e.g., V_{OUT}). In one example, the amplifier 100 is a class AB complementary arrangement including the input transistors 120a, 120b that form an emitter follower along with the output transistors 130a and 130b, 140a and 140b, and 150a and 150b. The current setting resistor 122 sets an idle current for the input transistors 120a, 120b. The use of multiple output transistors 130a-130b, 140a-140b, and 150a-150b in the class AB configuration results in a high peak output current capability, a distortion reduction, a higher linearity, an extended bandwidth, and stress-free reliability. The resistors 132a-132c, 142a-142c, and 152a-152c provide a thermal bias stability for the output stages 104a-104n and provide an output current balance between the output currents of the individual output transistors 130a-130c, 140a-140c, and 150a-150c.

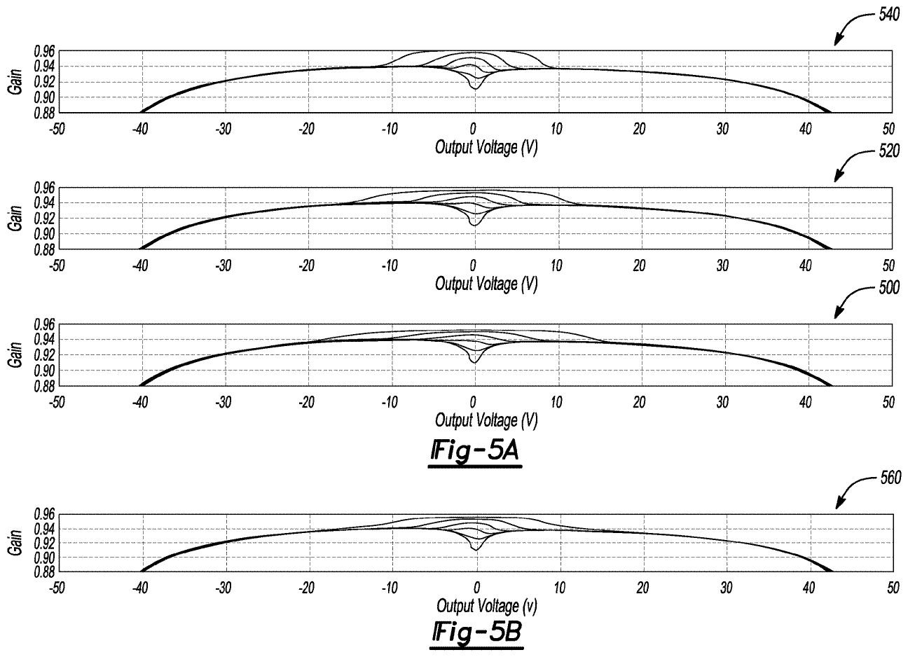

FIGS. 5A and 5B depict a simulation for various push-pull complementary pair with an incremental gain with different bias setting and an output stage overall gain in accordance with one embodiment. FIG. 5A depicts various plots 500, 520, and 540 which correspond to the gain of individual output stages 104a-104n of the amplifier 300 of FIG. 300 illustrated in connection with FIG. 4 against an output voltage at different bias levels. For example, the plot 500 generally depicts the gain for the first output stage 104a where the output transistors (or output devices) 130a-130b operate at higher quiescent current. Similarly, the plot 520 generally depicts the gain for the stage 104b where the output transistors 140a-140b operate at moderate quiescent current. In addition, the plot 540 generally depicts the gain and resistance for the output stage 104n where the output transistors 150a-150b operate at lower quiescent current.

FIG. 5B depicts a plot 560 which correspond to an overall gain of the amplifier 300 as shown in connection with FIG. 3 against different bias levels. The plot 560 illustrates an overall gain plot is comprised of a superposition of gain plots for the individual output stages 104a-104n, shown in FIG. 5A. The overall transition from low output current to high output current in the amplifier 300 takes place in a consecutive manner, one individual output stage after another; the overall transition is smoothly shaped,

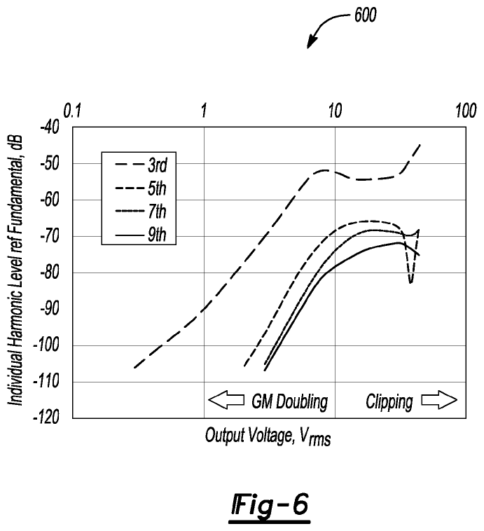

FIG. 6 depicts one example of a plot 600 showing an individual harmonic distortion as a function of an output voltage for an overbiased push-pull output stage of the amplifier 300 of FIG. 4. The amplifier 300 exhibits high order harmonics 3-6 dB that are lower, than a conventional push-pull output stage having multiple output devices.

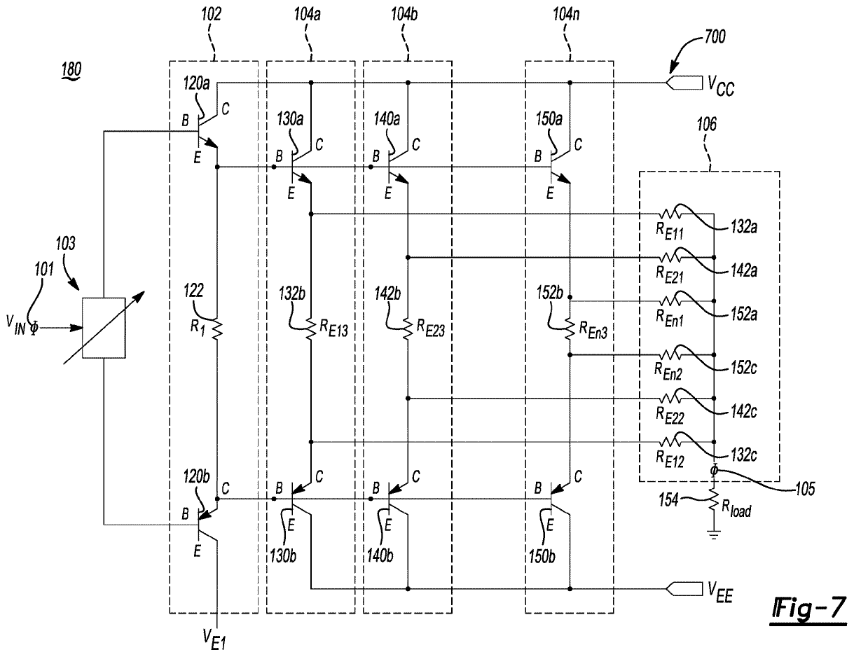

FIG. 7 depicts an amplifier 700 in accordance with one embodiment of the present disclosure. Similar to the amplifiers 100 and 300 noted above, the amplifier 300 may be implemented as a Class AB amplifier. The amplifier 700 includes the input stage 102, the plurality of output stages 104a-104n and the combining stage 106. It is recognized that the number of output stages 104a-104n may vary based on the desired criteria of a particular implementation. The input terminal 101 receives an input voltage, V_{IN}. In general, the input voltage, V_{IN} is present on an input signal (e.g., an audio signal) that requires amplification and the output terminal 105 of the amplifier 700 provides the output signal, V_{OUT}. Similar to the amplifier 300 noted above, the amplifier 700 is generally configured to also operate in the push mode and in the pull mode.

Similar to the amplifier 100 as noted above, the amplifier 700 includes the first output stage 104a having the first output transistors 130a, 130b and a current setting resistor 132b (or R_{E13}). The second output stage 104b includes the second output transistors 140a, 140b and a current setting resistor 142b (or R_{E23}). The third output stage 104c includes the third output switches 150a, 150b and a current setting resistor 152b (or R_{En3}). The combining stage 106 includes resistor 132a (R_{E11}), resistor 132c (R_{E12}), resistor 142a (R_{E21}), resistor 142c (R_{E22}), resistor 152a (R_{En1}), resistor 152c (R_{En2}). In general, the current setting resistor 132b of the first output stage 104a is coupled to the resistors 132a and 132c of the combining stage 106 via a delta connection. Similarly, the current setting resistor 142b of the second output stage 104b is coupled to the resistors 142a and 142c of the combining stage 106 via a delta connection. Similarly, the current setting resistor 152b of the second output stage 104n is coupled to the resistors 152a and 152c of the combining stage 106 via a delta connection.

The amplifier 100 generally operates in the following manner in connection with the push mode. As shown at the input stage 102, the first voltage (e.g., V_{C1}) is provided to a collector of the input transistor 120a. The input voltage (e.g., V_{IN}) is provided to a base of the input transistor 120a. Thus, when the first voltage V_{C1} is applied to the input transistor 120a, the input transistor 120a generates a voltage that is provided to a base of the output transistors 130a, 140a, and 150a of the output stages 104a, 104b, and 104c.

The third voltage (e.g., V_{CC}) is provided to collectors of the output transistors 130a, 140a, and 150b of the output stages 104a, 104b, and 104n, respectively such that the output transistors 130a, 140a, and 150a provide a first output voltage (or a first output current) to the resistors 132a, 132c, 142a, 142c, 152a and 152c of the combining stage 106. It is recognized that the input transistor 120a provides a voltage to the bases of the output transistors 130a, 140a, and 150a when the third voltage V_{CC} is applied to the output transistors 130a, 140a, and 150a. In general, the current setting resistors 132b, 142b, and 152b serve as biasing resistors. For example, the current setting resistors 132b, 142b, and 152b set the quiescent current (current in the absence of the input signal) through each individual output stage 104a, 104b, and 104n. Each of the output stages 104a, 104b, and 104b provide the first voltage to the resistors 132a and 132c, 142a and 142c, 152a and 152c, respectively, of the combining stage 106. The combining stage 106 sums the current through the resistors 132a, 132c, 142a, 142c, 152a, 152c and provides the current to the resistor 154 (e.g., R_{load})). The resistors 132a and 132c, 142a and 142c, and 152a and 152c may be sufficiently small to achieve a low impedance output. However, such resistors 132a and 132c, 142a and 142c, and 152a and 152c may be large enough to prevent excessive quiescent current. In short, in the push mode, the direction of the current is positive via the V_{CC} rail, through the output transistors 130a, 140a, 150a to the resistors 132a and 132c, 142a and 142c, 152 and 152c, respectively, and to the resistor 154 of the combining stage 106 and then to ground.

In one example, the values of emitter and summing network resistors in the amplifier 300 and the amplifier 700 can be established by basic Y (e.g., star connection)−Δ (delta connection) transformation.

By setting the various resistance values for the current setting resistors 132b, 142b, 152b and for the resistors 132a, 132c, 142a, 142c, and 152a, 152c and/or by establishing the delta connections as noted above, these aspect(s) enable the amplifier 700 to, among other things, provide a driving output from each of the output stages 104a-104n and the combining stage 106 to produce a low distortion output signal at the load (or at the resistor 156). Each of the output stages 104a, 104b, and 104b and the resistors 132a, 142a, 152a of the combining stage 106 generate the output voltage V_{OUT} (e.g., a positive half cycle of the output voltage) that is provided to the resistor 154 (e.g., R_{load})). The controller 180 may be operably coupled to the amplifier 100 to selectively apply the first voltage V_{C1}, the second voltage V_{E1}, the third voltage V_{CC}, and the fourth voltage V_{EE}.

As noted above, in an effort to provide a negative half cycle of the output voltage V_{OUT}, the amplifier 100 also operates in the pull mode. Through the negative half cycle of the output voltage (V_{OUT}), the output current is returned to the negative rail through the resistors 132c, 142c, and 152c of the combining stage 106 and through the output transistors 130b, 140b, and 150b of the output stages 104a, 104b, 104n, respectively. In this case, the controller 180 may apply the fourth voltage (e.g., V_{EE}) to the output transistors 130b, 140b, and 150b to enable the current flow from the emitters to the collectors for these output transistors 130b, 140b, and 150b. In the pull mode, the output transistors 130b, 140b, and 150b are switched on and the current flows through the load (or the resistor 150), resistors 132c, 142c, and 152c of the combining stage 106 and the output transistors 130b, 140b, and 150b, respectively, of the output stages 104a-104c.

In general, by adding the corresponding output stages 104a-104n along with the combining stage 106, the amplifier 100 is generally configured to increase output capability for driving the load (e.g., R_{load}) with a final output voltage (e.g., V_{OUT}). In one example, the amplifier 700 is a class AB complementary arrangement including the input transistors 120a, 120b that form an emitter follower air along with the output transistors 130a and 130b, 140a and 140b, and 150a and 150b. The current setting resistor 122 sets an idle current for the input transistors 120a, 120b. The use of multiple output transistors 130a-130b, 140a-140b, and 150a-150b in the class AB configuration results in a high peak output current capability, a distortion reduction, a higher linearity, an extended bandwidth, and stress-free reliability. The resistors 132a-132c, 142a-142c, and 152a-152c provide a thermal bias stability for the various output stages 104a-104n and also provide an output current balance between the individual output pairs of output transistors 130a-130c, 140a-140c, and 150a-150c.

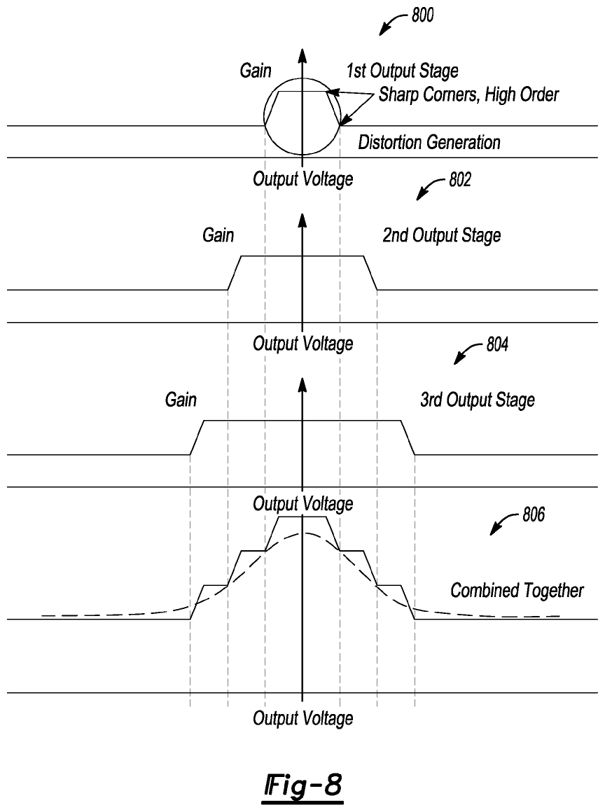

FIG. 8 depict gain plots 800, 802, 804, and 806 that illustrate characteristics for the disclosed amplifiers 300, 700 of FIGS. 4 and 7 in accordance with one embodiment of the present disclosure. Gain plot 800 generally illustrates the gain as provided from the first output stage 104a, that operates at lower quiescent current. Gain plot 800 illustrates the presence of sharp corners and the creation of harmonics. Gain plot 802 generally illustrates the gain as provided from the second output stage 104b that operates at moderate quiescent current. Gain plot 804 generally illustrates the gain as provided from the third output stage 104n that operates at higher quiescent current. Gain plot 806 generally illustrates the combination of the gains from the first output stage 104a, the second output stage 104b, and the third output stage 104c. Gain plot 806 generally depicts that one step in the gain with, for example, several smaller steps, providing smooth overall transfer function and preventing generation of high order harmonics.

It is recognized that the controllers as disclosed herein may include various microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, such controllers as disclosed utilizes one or more microprocessors to execute a computer-program that is embodied in a non-transitory computer readable medium that is programmed to perform any number of the functions as disclosed. Further, the controller(s) as provided herein includes a housing and the various number of microprocessors, integrated circuits, and memory devices ((e.g., FLASH, random access memory (RAM), read only memory (ROM), electrically programmable read only memory (EPROM), electrically erasable programmable read only memory (EEPROM)) positioned within the housing. The controller(s) as disclosed also include hardware-based inputs and outputs for receiving and transmitting data, respectively from and to other hardware-based devices as discussed herein.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An amplifier comprising:
an input stage including a first input transistor and a second input transistor to receive an input signal;
a plurality of output stages, each output stage includes a plurality of output resistors, the plurality of output stages being configured to operate in a one of a push mode to output a positive cycle of the input signal to a load and a pull mode to absorb a negative cycle of the input signal from the load; and
a combining stage including a plurality of combining resistors, each combining resistor forming a star connection with the plurality of output resistors for each output stage to receive a first voltage therefrom and to generate an output voltage based on the first voltage to produce a low distortion output signal at the load.

2. The amplifier of claim 1, wherein each of the plurality of output stages includes a first output transistor and a second output transistor, the first output transistor and the second output transistor each having an emitter that is coupled to at least one of the plurality of output resistors.

3. The amplifier of claim 1, wherein each of the plurality of output stages includes a first output transistor, a second output transistor, a first output resistor, and a second output resistor, and wherein the first output transistor includes an emitter that is coupled to the first output resistor and the second output transistor includes an emitter that is coupled to the second output resistor.

4. The amplifier of claim 3, wherein a resistance of the first output resistor is similar to a resistance of the second output resistor.

5. The amplifier of claim 3, wherein the first output transistor and the first output resistor provide the first voltage to the at least one combining resistor in the push mode.

6. The amplifier of claim 3, wherein the second output transistor and the second output resistor are configured to receive a second voltage from the at least one combining resistor in the pull mode.

7. The amplifier of claim 3, wherein a sum of a resistance of the first output resistor and a first combining resistor of the combining stage is similar to a sum of a resistance of the second output resistor and a second combining resistor to enable the load to receive the low distortion output signal.

8. An amplifier comprising:
an input stage including a first input transistor and a second input transistor to receive an input signal;
a plurality of output stages, each output stage includes at least one current setting resistor, the plurality of output stages being configured to operate in a one of a push mode to output a positive cycle of the input signal to a load and a pull mode to absorb a negative cycle of the input signal from the load; and
a combining stage including a plurality of combining resistors, each combining resistor being positioned in series each output stage, respectively, and forming a delta connection with a corresponding current setting resistor to receive a first voltage therefrom and to generate an output voltage based on the first voltage to produce a low distortion output signal at the load.

9. The amplifier of claim 8, wherein each of the plurality of output stages includes a first output transistor, a second output transistor, and at least one output resistor, and wherein the first output transistor and the second output transistor each include an emitter that is coupled to the at least one output resistor.

10. The amplifier of claim 8, wherein each of the plurality of output stages includes a first output transistor, a second output transistor, a first output resistor and a second output resistor, and wherein the first output transistor includes an emitter that is coupled to the first output resistor and the second output transistor includes an emitter that is coupled to the second output resistor.

11. The amplifier of claim 10, wherein a resistance of the first output resistor is similar to a resistance of the second output resistor.

12. The amplifier of claim 10, wherein the first output transistor and the first output resistor provide the first voltage to the at least one combining resistor in the push mode.

13. The amplifier of claim 10, wherein the second output transistor and the second output resistor are configured to receive a second voltage from the at least one combining resistor in the pull mode.

14. The amplifier of claim 8, wherein a sum of a resistance of a first output resistor of at least one of the plurality of output stages and a resistance of a first combining resistor of the combining stage is similar to a sum of a resistance of a second output resistor of the at least one of the plurality of output stages and resistance of a second output resistor of a second combining resistor to enable the load to receive the low distortion output signal.

15. The amplifier of claim 8 is one of a class A, class B, and class AB amplifier.

16. An amplifier comprising:
a plurality of output stages, each output stage includes at least one output resistor, the plurality of output stages being configured to operate in a one of a push mode to output a positive cycle of an input signal to a load and a pull mode to absorb a negative cycle of the input signal from the load; and
a combining stage including a plurality of combining resistors, each combining resistor forming a star connection with the at least one output resistor for each output stage to receive a first voltage therefrom and to generate an output voltage based on the first voltage to produce a low distortion output signal at the load.

17. The amplifier of claim 16, wherein each of the plurality of output stages includes a first output transistor and a second output transistor, the first output transistor and the second output transistor each having an emitter that is coupled to the at least one output resistor.

18. The amplifier of claim 16, wherein each of the plurality of output stages includes a first output transistor, a second output transistor, a first output resistor, and a second output resistor, and wherein the first output transistor includes an emitter that is coupled to the first output resistor and the second output transistor includes an emitter that is coupled to the second output resistor.

19. The amplifier of claim 18, wherein a resistance of the first output resistor is similar to a resistance of the second output resistor.

20. The amplifier of claim 16, wherein a sum of a resistance of a first output resistor of at least one of the plurality of output stages and a resistance of a first combining resistor of the combining stage is similar to a sum of a resistance of a second output resistor of the at least one of the plurality of output stages and resistance of a second output resistor of a second combining resistor to enable the load to receive the low distortion output signal.
